(19) United States
(12) Patent Application Publication
(10) Pub. No.: US 2017/0263735 A1
(43) Pub. Date: Sep. 14, 2017

(54) Method of Manufacturing Thin Film Transistor (TFT) and TFT

(71) Applicants: BOE Technology Group Co., Ltd., Beijing (CN); Hefei Xinsheng Optoelectronics Technology Co., Ltd, Hefei City (CN)

(72) Inventor: Jun Cheng, Beijing (CN)

(21) Appl. No.: 15/282,270

(22) Filed: Sep. 30, 2016

(30) Foreign Application Priority Data
Mar. 14, 2016 (CN) 201610144788.2

(51) Int. Cl. H01L 29/66; H01L 27/12; H01L 21/441; H01L 21/02; H01L 29/786; H01L 21/426

(52) U.S. Cl. CPC H01L 29/66969; H01L 29/7869; H01L 21/426; H01L 21/441; H01L 21/02274; H01L 27/1259

(57) ABSTRACT

A method of manufacturing a thin-film transistor (TFT) and a TFT are provided. The method of manufacturing the TFT includes, after depositing a semiconductor layer, oxidizing regions of the semiconductor layer corresponding to sputtering target gaps, so that oxygen vacancies at the regions corresponding to the sputtering target gaps can be decreased and oxygen vacancies on the semiconductor layer can be more uniform.

This application claims priority to and the benefit of Chinese Patent Application No. 201610144788.2 filed on Mar. 14, 2016, which application is incorporated herein in its entirety.

### TECHNICAL FIELD

Embodiments of the present disclosure relate to a method of manufacturing a thin-film transistor (TFT) and a TFT.

### BACKGROUND

In recent years, display technology has been rapidly developed. For example, the TFT technology is developed from the original amorphous silicon (a-Si) TFT to the current low-temperature polycrystalline silicon (LTPS) TFT, metal induced laterally crystallized (MILC) TFT, oxide TFT, and the like. And the luminous technology is also developed from the original liquid crystal display (LCD) and plasma display panel (PDP) to the current organic light-emitting diode (OLED) display.

The OLED display is a new-generation display device, which has advantages, such as self-illumination, rapid response speed, wide viewing angle, compared with the LCD, and it can be applied in flexible display, transparent display, 3D display, or the like.

### SUMMARY

Embodiments of the present disclosure provide a method of manufacturing thin film transistor and thin film transistor.

According to at least one embodiment of the present disclosure, a method of manufacturing a thin-film transistor (TFT), including: forming a semiconductor layer; oxidizing regions of the semiconductor layer corresponding to sputtering target gaps, so as to decrease oxygen vacancies at the regions corresponding to the sputtering target gaps; and forming a channel region, a source region and a drain region on the semiconductor layer.

For example, the method further including: applying photoresist on the semiconductor layer, removing photoresist at the regions of the semiconductor layer corresponding to the sputtering target gaps, and oxidizing the semiconductor layer.

For example, the method further including: forming a gate electrode layer on a substrate; forming a gate insulating layer on the gate electrode layer, and depositing a semiconductor layer on the gate insulating layer; depositing source-drain metal layer at two end portions of the semiconductor layer, and forming a source electrode and a drain electrode by a photolithographic process; depositing a passivation layer on the source-drain metal layer, and forming at least one of a source electrode contact hole, or a drain electrode contact hole on the passivation layer; and depositing a transparent electrode layer on the passivation layer, and forming a contact electrode by a photolithographic process.

For example, gas for oxidizing the semiconductor layer is selected from a group consisting of oxygen, ozone, nitrous oxide or hydrogen peroxide.

For example, the semiconductor layer includes an oxide semiconductor.

For example, material of the oxide semiconductor is at least one oxide of indium, gallium, zinc or tin.

For example, the method further including: forming an etch stop layer on the channel region to form an etching protective region, depositing the source-drain metal layer on the etch stop layer, and forming the source electrode and the drain electrode by a photolithographic process.

For example, the etch stop layer includes a single-layered or multi-layered structure formed by at least one material selected from a group consisting of silicon oxide, silicon nitride, hafnium oxide and aluminum oxide.

For example, the gate electrode layer includes a single-layered or a multi-layered composite structure formed by at least one material selected from a group consisting of molybdenum, molybdenum-niobium alloy, aluminum, aluminum-neodymium alloy, titanium and copper; and the gate electrode layer has a thickness of 100 nm-3,000 nm.

For example, the gate insulating layer includes a single-layered or a composite structure formed by at least one material selected from a group consisting of silicon oxide, silicon nitride, hafnium oxide, silicon oxynitride and aluminum oxide.

For example, the gate insulating layer is formed by a plasma enhanced chemical vapor deposition (PECVD) process.

For example, the source electrode and the drain electrode include a single layered or a multi-layered composite structure formed by at least one material selected from a group consisting of molybdenum, molybdenum-niobium alloy, aluminum, aluminum-neodymium alloy, titanium and copper.

For example, the transparent electrode layer is made of indium tin oxide (ITO), and the forming method of the transparent electrode layer includes: forming an amorphous ITO film by a sputtering process; and crystallizing the amorphous ITO film by an annealing process, and forming the transparent electrode layer with a thickness of 20-150 nm.

For example, the substrate is a glass substrate or a flexible plastic substrate.

According to embodiments of the present disclosure, a thin film transistor (TFT) is provided, including: a gate electrode layer, a gate insulating layer, a source electrode, a drain electrode, a semiconductor layer, a passivation protective layer and ITO electrode layer, which is manufactured by the manufacturing method.

### BRIEF DESCRIPTION OF THE DRAWINGS

Embodiments of the present disclosure will be described in more detail as below in conjunction with the accompanying drawings to enable those skilled in the art to understand the present disclosure more clearly, in which,

FIG. 1 is a schematic structural view illustrating a step of forming a gate electrode on a substrate in an embodiment of the present disclosure;

FIG. 2 is a schematic structural view illustrating a step of forming a gate dielectric layer in an embodiment of the present disclosure;

FIG. 3 is a schematic structural view illustrating a step of forming a semiconductor layer in an embodiment of the present disclosure;

FIG. 4 is a schematic structural view illustrating a step of depositing an etch stop layer and forming a source electrode and a drain electrode in an embodiment of the present disclosure;

FIG. 5 is a schematic structural view illustrating a step of forming a passivation layer in an embodiment of the present disclosure;

FIG. 6 is a schematic structural view illustrating a step of forming a transparent electrode layer and a contact electrode in an embodiment of the present disclosure; and

FIG. 7 is a schematic structural view illustrating a step of oxidizing regions of the semiconductor layer corresponding to sputtering target gaps.

### DETAILED DESCRIPTION

Embodiments of the present disclosure will be described in details in connection with the drawings related to the embodiments of the present disclosure. It is apparent that the described embodiments are just a part but not all of the embodiments of the present disclosure. Based on the described embodiments herein, an ordinary skill in the art can obtain other embodiment(s), without any inventive work, which should be within the scope of the present disclosure.

Unless otherwise defined, all the technical and scientific terms used herein have the same meanings as commonly understood by one of ordinary skill in the art to which the present disclosure belongs. The terms, such as “first,” “second,” or the like, which are used in the description and the claims of the present application, are not intended to indicate any sequence, amount or importance, but for distinguishing various components. Also, the terms, such as “a/an,” “the,” or the like, are not intended to limit the amount, but for indicating the existence of at lease one. The terms, such as “comprise/comprising,” “include/including,” or the like are intended to specify that the elements or the objects stated before these terms encompass the elements or the objects and equivalents thereof listed after these terms, but not preclude other elements or objects. The terms, “on,” “under,” or the like are only used to indicate relative position relationship, and when the position of the object which is described is changed, the relative position relationship may be changed accordingly.

In an active matrix organic light-emitting diode (AMOLED) display, each pixel is equipped with a switch, namely a TFT, for controlling the pixel. Thus, each pixel may be independently controlled through a drive circuit, and other pixels would not be affected by crosstalk, or the like. The TFT at least includes a gate electrode, a source electrode, a drain electrode, a gate insulating layer and an active layer.

The inventor found that, in the method of manufacturing the TFT, in the process of depositing a thin film by sputtering targets, a plurality of targets are combined together, and an oxide thin film, formed at positions right opposite to the targets and at regions right opposite to target gaps, has different oxygen vacancies. When this process is applied in a method for fabricating a TFT display, Mura regions (regions with non-uniform brightness) parallel to the targets will be formed, and the brightness of the Mura regions will be lower than that of non-Mura regions. This phenomenon will become more serious with the operating time.

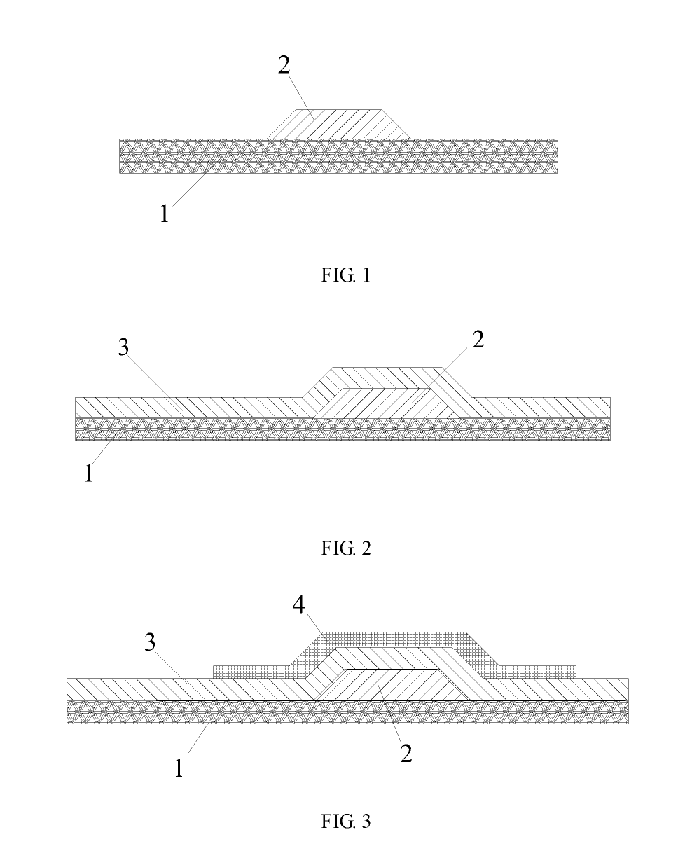

Detailed description will be given below to the technical proposals with reference to the accompanying drawings in embodiments of the present disclosure. As illustrated in FIGS. 1 to 7, embodiments of the present disclosure provide a method of manufacturing a TFT, which includes:

S1: forming a gate electrode layer 2 on a substrate 1;

S2: forming a gate insulating layer 3 on the gate electrode layer 2;

S3: forming a semiconductor layer 4 on the gate insulating layer 3, oxidizing regions of the semiconductor layer 4 corresponding to sputtering target gaps, so as to decrease oxygen vacancies at the regions corresponding to the sputtering target gaps, and forming a channel region, a source region and a drain region on the semiconductor layer 4.

In the method of manufacturing the TFT provided by the embodiment of the present disclosure, after the step of depositing the semiconductor layer 4, oxidizing treatment is performed on the regions of the semiconductor layer 4 corresponding to the sputtering target gaps, so as to decrease the oxygen vacancies at the regions corresponding to the sputtering target gaps. In this way, oxygen vacancies on the semiconductor layer 4 can be more uniform. The method can avoid Mura of targets caused by the manufacturing process of the thin-film technology, and the brightness uniformity of the TFT display is improved.

For instance, the TFT provided by the embodiment of the present disclosure is an oxide TFT, namely the active layer includes an oxide semiconductor layer. Some characteristics of a TFT with an oxide semiconductor as the active layer are superior to those of a-Si, such as mobility, on-state current, switching characteristic, and the like. Although the characteristics of the oxide TFT are not superior to a polycrystalline silicon (poly-Si) TFT, the oxide TFT is sufficient for applications which require rapid response and large current, such as high-frequency, high-resolution and large-scale displays and OLED displays. Oxide TFT has good uniformity. Compared with poly-Si, no compensating circuit is required as the problem of uniformity does not exist, the oxide TFT has advantages on the mask number and the production difficulty in the method of fabricating it. The oxide TFT also has no difficulty when it is used in fabricating a large-scale display. Moreover, sputtering and the like can be adopted for producing it and no additional device is required, so the oxide TFT has cost advantage. Oxide semiconductor materials adopted by the oxide TFT have good semiconductor characteristics when having high oxygen content and have low resistivity when having low oxygen content, so it can be used as transparent electrodes. For instance, the oxide semiconductor layer 4 is made from oxide(s) of one or more of indium, gallium, zinc and tin, such as indium gallium zinc oxide (IGZO), indium zinc oxide (IZO), InSnO (ITO) and indium gallium tin oxide (InGaSnO). The material of the semiconductor layer 4 of the TFT may also include a-Si, poly-Si, organic semiconductors, or the like. In this way, the Mura regions of the TFT display can be reduced and the brightness uniformity of the display can be improved.

In the process of manufacturing a TFT, a substrate 1 is prepared at first. The substrate 1 may be a glass substrate or a quartz substrate and may also be a flexible substrate (e.g., a plastic substrate). For instance, the substrate 1 is a glass substrate which can resist high temperature. As illustrated in FIG. 1, a gate electrode layer 2 is deposited on the substrate 1, and a gate electrode may be formed by a first photolithographic process. The gate electrode layer 2 includes a single-layered film or a multi-layered composite laminates formed by one or more materials selected from molybdenum, molybdenum-niobium alloy, aluminum, aluminum-neodymium alloy, titanium and copper, e.g., a single-layered film or multi-layered composite film formed by molybdenum, aluminum or molybdenum-aluminum alloy. The thickness of the gate electrode layer 2 is 100 nm to 3,000 nm.

As illustrated in FIG. 2, a gate insulating layer 3 is deposited on the gate electrode after the step of forming the gate electrode. For instance, the gate insulating layer 3 includes: a single-layered film or multi-layered composite film formed by one or two selected from a group consisting of SiOx, SiNx, HfOx, SiON and AlOx. The gate insulating layer 3 is formed by a plasma enhanced chemical vapor deposition (PECVD) process.

As illustrated in FIG. 3, a semiconductor layer 4 is deposited on the gate insulating layer 3. The semiconductor layer 4 may be directly deposited on the gate insulating layer 3 by magnetron sputtering. For instance, the semiconductor layer 4 includes oxide semiconductors, such as metal oxide. The oxide semiconductors are made from oxide(s) of one or more selected from indium, gallium, zinc and tin, for example, IGZO, IZO, InSnO and InGaSnO. As illustrated in FIG. 7, photoresist 8 is applied after the step of depositing the semiconductor layer 4, and the photoresist 8 at regions of the semiconductor layer 4 corresponding to sputtering target gaps is removed, so that the photoresist 8 can be alternately arranged on the semiconductor layer 4 to form strip regions; and subsequently, oxidizing treatment is performed on the deposited oxide film, and oxygen vacancies on the portions of the semiconductor layer 4 on which the photoresist 8 is removed are decreased (namely oxygen vacancies on the regions of the semiconductor film corresponding to the sputtering target gaps are decreased), so that the oxygen vacancies can be more uniformly distributed on the entire semiconductor layer 4, and the brightness uniformity of the oxide TFT display can be improved. Gas for oxidizing the semiconductor layer 4 includes: oxygen, ozone, nitrous oxide or hydrogen peroxide.

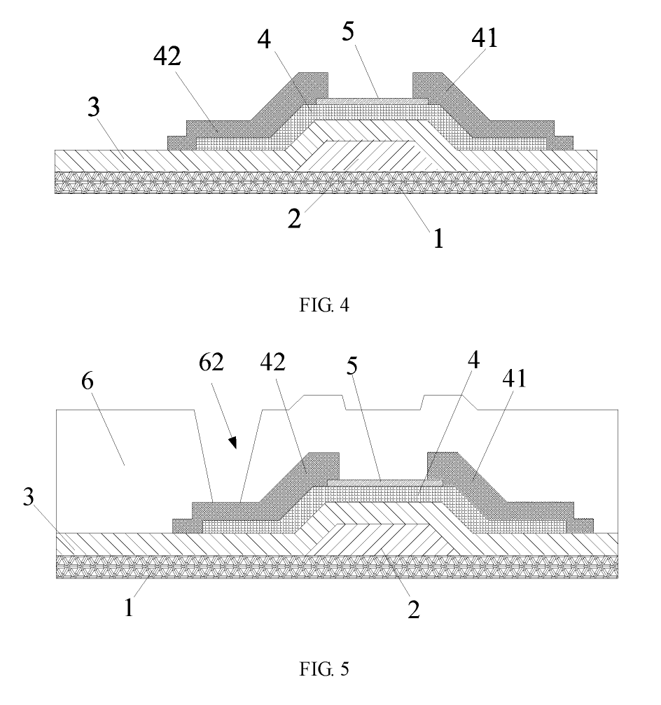

As illustrated in FIG. 4, a channel region, a source region and a drain region are formed on the oxide semiconductor layer 4 by a second photolithographic process, and an etch stop layer 5 is deposited on the channel region. The etch stop layer 5 includes: a single-layered film or multi-layered film structure formed by oxide(s) of one or more selected from SiOx, SiNx, HfOx or AlOx. The etch stop layer has low hydrogen content. An etching protective layer is formed by a third photolithographic process. Source-drain metal layer is deposited on the etch stop layer 5, and a source electrode 41 and a drain electrode 42 are formed by a fourth photolithographic process. The source electrode 41 and the drain electrode 42 include a single layered film or a multi-layered composite film structure or laminates formed by one or more materials selected from molybdenum, molybdenum-niobium alloy, aluminum, aluminum-neodymium alloy, titanium and copper.

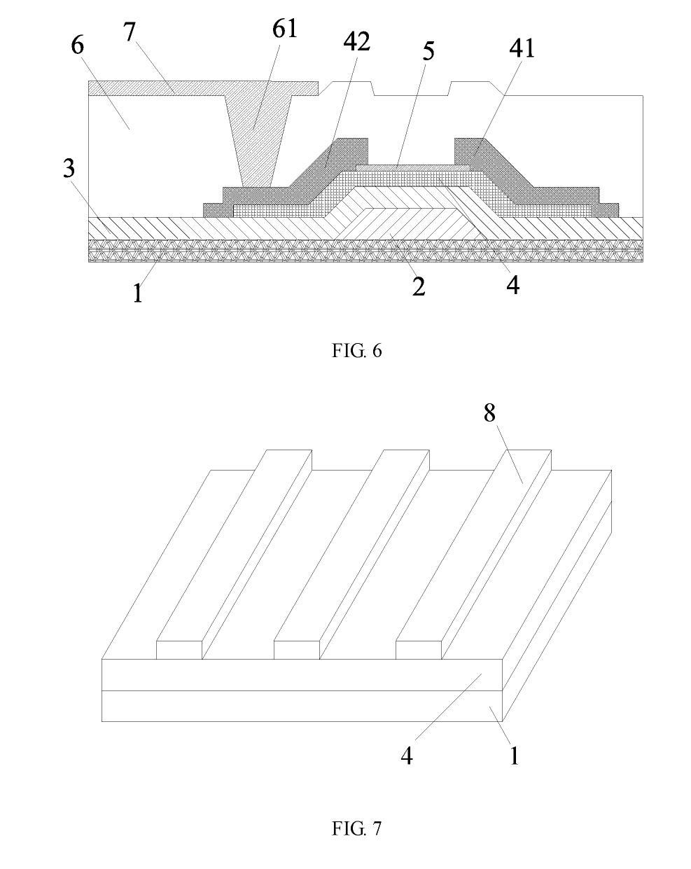

As illustrated in FIG. 5, after the source and drain electrodes 42 are formed, a passivation layer 6 is deposited on the source and drain metal. The passivation layer 6 may include a single-layered film or multi-layered film structure formed by one or more materials selected from SiOx, SiNx, HfOx and AlOx. The passivation layer 6 may be formed by a PECVD process and has low hydrogen content and good surface behavior. After the passivation layer 6 is formed, a source electrode contact hole and/or a drain electrode contact hole 62 are/is formed on the passivation layer 6 by a photolithographic process. As illustrated in FIG. 6, only a drain electrode contact hole 62 is formed on the passivation layer 6, and a transparent electrode layer 7 is deposited on the passivation layer 6. The transparent electrode layer 7 is made from ITO. In this case, a contact electrode 61 is formed in the transparent drain electrode contact hole, and the drain electrode 42 is connected with the transparent electrode layer 7 through the contact electrode 61. In the embodiment, only the drain electrode contact hole 62 is formed, and the contact electrode 61 made from ITO is formed in the drain electrode contact hole 62. It is noted that it is also possible that only a source electrode contact hole is formed on the passivation layer 6 or a source electrode contact hole and a drain electrode contact hole 62 are simultaneously formed, and the contact electrode(s) 61 is/are formed in the contact hole(s).

For instance, the transparent electrode layer 7 is made from ITO. The forming method includes: forming an amorphous ITO film by a sputtering process, and crystallizing the amorphous ITO film by annealing it. The thickness of the transparent electrode layer 7 is 20-150 nm.

It is noted that the embodiment of the present disclosure illustrates the manufacturing method of a bottom-gate TFT. It is understood by one of ordinary skill in the art that the method of “oxidizing the regions of the semiconductor layer corresponding to the sputtering target gaps, so as to decrease the oxygen vacancies at the regions corresponding to the sputtering target gaps” in the manufacturing process of the TFT is also applicable to a manufacturing process of a top-gate TFT. For instance, it can also avoid Mura of the targets caused by the manufacturing process of the thin-film technology.

The embodiments of the present disclosure further provide a thin film transistor, which includes a gate electrode layer 2, a gate insulating layer 3, a source electrode 41, a drain electrode 42, a semiconductor layer 4, a passivation protective layer and an ITO electrode layer, and is manufactured by the method of manufacturing the TFT.

As oxidizing treatment is performed on the regions of the semiconductor layer 4 corresponding to the sputtering target gaps in the manufacturing process and the oxygen vacancies at the regions corresponding to the sputtering target gaps are reduced, the oxygen vacancies on the semiconductor layer 4 can be more uniform. The method can avoid Mura of the targets caused by the manufacturing process of the thin-film technology and improve the brightness uniformity of the TFT display.

The embodiments of the present disclosure provide a method of manufacturing a thin film transistor (TFT). In the method, a gate electrode layer is formed on a substrate at first; a gate insulating layer and a semiconductor layer are formed; after the semiconductor layer is formed, oxidizing treatment is performed on the regions of the semiconductor layer corresponding to the sputtering target gaps, so as to reduce the oxygen vacancies at the regions corresponding to the sputtering target gaps. Thus, the oxygen vacancies on the semiconductor layer can be more uniform. The method can avoid Mura of the targets caused by the manufacturing process of the thin-film technology and improve the brightness uniformity of the TFT display.

It is noted that: the foregoing embodiments are only used for illustrating the embodiments of the present disclosure and not intended to limit the embodiments of the present disclosure. Although detailed description is given with reference to the foregoing embodiments, it should be understood by an ordinary skill in the art that modification may also be made to the foregoing embodiments or equivalents may be made to some features or elements; and the modifications or equivalents shall not allow the essence of corresponding embodiments to depart from the spirit and the scope of the present disclosure.

The application claims benefit of and priority to the Chinese patent application No. 201610144788.2 filed in SIPO on Mar. 14, 2016 and entitled “a Method of Manufacturing Thin Film Transistor and Thin Film Transistor”, which is incorporated herein by reference in its entirety.

What is claimed is:

1. A method of manufacturing a thin-film transistor (TFT), comprising:
forming a semiconductor layer;
oxidizing regions of the semiconductor layer corresponding to sputtering target gaps, so as to decrease oxygen vacancies at the regions corresponding to the sputtering target gaps; and
forming a channel region, a source region and a drain region on the semiconductor layer.

2. The method of manufacturing the TFT according to claim 1, further comprising: applying photoresist on the semiconductor layer, removing photoresist at the regions of the semiconductor layer corresponding to the sputtering target gaps, and oxidizing the semiconductor layer.

3. The method of manufacturing the TFT according to claim 1, further comprising:
forming a gate electrode layer on a substrate;
forming a gate insulating layer on the gate electrode layer, and depositing a semiconductor layer on the gate insulating layer;
depositing source-drain metal layer at two end portions of the semiconductor layer, and forming a source electrode and a drain electrode by a photolithographic process;
depositing a passivation layer on the source-drain metal layer, and forming at least one of a source electrode contact hole or a drain electrode contact hole on the passivation layer; and
depositing a transparent electrode layer on the passivation layer, and forming a contact electrode by a photolithographic process.

4. The method of manufacturing the TFT according to claim 1, wherein gas for oxidizing the semiconductor layer is selected from a group consisting of oxygen, ozone, nitrous oxide or hydrogen peroxide.

5. The method of manufacturing the TFT according to claim 1, wherein the semiconductor layer includes an oxide semiconductor.

6. The method of manufacturing the TFT according to claim 5, wherein material of the oxide semiconductor is at least one oxide of indium, gallium, zinc or tin.

7. The method of manufacturing the TFT according to claim 3, further comprising: forming an etch stop layer on the channel region to form an etching protective region, depositing the source-drain metal layer on the etch stop layer, and forming the source electrode and the drain electrode by a photolithographic process.

8. The method of manufacturing the TFT according to claim 7, wherein the etch stop layer includes a single-layered or multi-layered structure formed by at least one selected from a group consisting of silicon oxide, silicon nitride, hafnium oxide and aluminum oxide.

9. The method of manufacturing the TFT according to claim 3, wherein the gate electrode layer includes a single-layered or a multi-layered composite structure formed by at least one selected from a group consisting of molybdenum, molybdenum-niobium alloy, aluminum, aluminum-neodymium alloy, titanium and copper; and the gate electrode layer has a thickness of 100 nm-3,000 nm.

10. The method of manufacturing the TFT according to claim 3, wherein the gate insulating layer includes a single-layered or a composite structure formed by at least one selected from a group consisting of silicon oxide, silicon nitride, hafnium oxide, silicon oxynitride and aluminum oxide.

11. The method of manufacturing the TFT according to claim 3, wherein the gate insulating layer is formed by a plasma enhanced chemical vapor deposition (PECVD) process.

12. The method of manufacturing the TFT according to claim 3, wherein the source electrode and the drain electrode include a single layered or a multi-layered composite structure formed by at least one selected from a group consisting of molybdenum, molybdenum-niobium alloy, aluminum, aluminum-neodymium alloy, titanium and copper.

13. The method of manufacturing the TFT according to claim 3, wherein the transparent electrode layer is made of indium tin oxide (ITO), and the forming method of the transparent electrode layer includes:
forming an amorphous ITO film by a sputtering process; and
crystallizing the amorphous ITO film by an annealing process, and forming the transparent electrode layer with a thickness of 20-150 nm.

14. The method of manufacturing the TFT according to claim 3, wherein the substrate is a glass substrate or a flexible plastic substrate.

15. A thin film transistor (TFT), comprising:
a gate electrode layer, a gate insulating layer, a source electrode, a drain electrode, a semiconductor layer, a passivation protective layer and ITO electrode layer, which is manufactured by the manufacturing method according to claim 1.
